(19) United States
(12) Patent Application Publication
(10) Pub. No.: US 2011/0042686 A1
(43) Pub. Date: Feb. 24, 2011

(54) SUBSTRATES AND METHODS OF FABRICATING DOPED EPITAXIAL SILICON CARBIDE STRUCTURES WITH SEQUENTIAL EMPHASIS

(75) Inventors: Jisheng Han, Calamvale (AU); Sima Dimitrijev, Shailer Park (AU); Li Wang, Robertson (AU); Philip Tanner, The Gap (AU); Leonie Hold, Sadliers Crossing (DE); Alan Iacopi, Thornlands (AU); Fred Kong, Kuraby (AU); Herbert Barry Harrison, Golden Beach (AU)

Correspondence Address: KOKKA & BACKUS, PC, 703 High Street, PALO ALTO, CA, 94301, US

(73) Assignee: Qs Semiconductor Australia Pty Ltd., East Melbourne (AU)

(21) Appl. No.: 12/543,478

(22) Filed: Aug. 18, 2009

(51) Int. Cl. H01L 29/24; H01L 21/04

(52) U.S. Cl. 257/77; 438/508; 438/270; 257/E29.104; 257/E21.054

(57) ABSTRACT

Embodiments of the invention relate generally to semiconductors and semiconductor fabrication techniques, and more particularly, to devices, integrated circuits, substrates, and methods to form silicon carbide structures, including doped epitaxial layers (e.g., P-doped silicon carbide epitaxial layers), by supplying sources of silicon and carbon with sequential emphasis. In some embodiments, a method of forming an epitaxial layer of silicon carbide can include depositing a layer in the presence of a silicon source, and purging gaseous materials subsequent to depositing the layer. Further, the method can include converting the layer into a sub-layer of silicon carbide in the presence of a carbon source and a dopant, and purging other gaseous materials. In some embodiments, the presence of the silicon source can be independent of the presence of the carbon source and/or the dopant.

### CROSS-REFERENCE TO RELATED APPLICATIONS

This application is related to U.S. Pat. No. 7,362,609, issued Apr. 22, 2008, and entitled “Memory Cell,” which is herein incorporated by reference for all purposes.

### FIELD

Embodiments of the invention relate generally to semiconductors and semiconductor fabrication techniques, and more particularly, to devices, integrated circuits, substrates, and methods to form silicon carbide structures, including doped epitaxial layers (e.g., P-doped silicon carbide epitaxial layers), by supplying sources of silicon and carbon with sequential emphasis.

### BACKGROUND

A variety of conventional memory cells structures have been developed in various memory technologies. Silicon carbide has been identified recently as a material that can be used to manufacture structures that can retain data in a non-volatile manner. While silicon carbide and methods of fabricating the same have been used to fabricate conventional semiconductor devices, such as light emitting devices (“LEDs”) devices and high power switching devices, traditional techniques for fabricating silicon carbide semiconductors may not be well-suited for manufacturing non-volatile memory devices. While functional, some conventional approaches use sources of silicon or carbon that include other elements, such as hydrogen, that might contribute to formation of undesirable structures. The other elements also may be used as a reducing agent for the precursors. Thus, the other elements typically are present during the various stages of the epitaxial process. Further, partial pressures of silicon sources or carbon sources in some approaches might combine with partial pressures due to, for example, oxygen and/or moisture (e.g., H₂O) to create total pressures that may not be well-suited to reduce contamination optimally.

Further, some conventional approaches add dopants at relatively high temperatures (e.g., above 1300° C.) with an aim to increase the electrical activity of some dopants in silicon carbide at such temperatures. For example, some approaches implant dopants at temperatures at or near 1370° C. In some instances, the relatively high temperatures at which dopants are added to the formation of silicon carbide may not be sufficiently compatible with other semiconductor processing technologies, such as some complementary metal oxide semiconductor (“CMOS”) processing technologies.

It is desirable to provide improved techniques, systems, integrated circuits, and methods that minimize one or more of the drawbacks associated with devices, integrated circuits, substrates, and methods for forming silicon carbide structures, such as P-doped epitaxial layers.

### BRIEF DESCRIPTION OF THE FIGURES

The invention and its various embodiments are more fully appreciated in connection with the following detailed description taken in conjunction with the accompanying drawings, in which:

FIG. 1 is a diagram depicting an example of a flow to form doped silicon carbide (e.g., P-doped silicon carbide) on a substrate, according to various embodiments of the invention;

FIG. 2 is a diagram depicting an example of a semiconductor wafer including a P-doped silicon carbide epitaxial layer, according to at least some embodiments of the invention;

FIG. 3 is a flow diagram depicting an example of a method for forming doped silicon carbide on a bulk substrate, according to various embodiments of the invention;

FIG. 4 is a diagram depicting an example of introducing precursors with sequential emphasis to form a doped silicon carbide epitaxial layer, according to various embodiments of the invention;

FIG. 5 is a flow diagram depicting another example of a method for forming doped silicon carbide on a bulk substrate, according to various embodiments of the invention;

FIG. 6 is a diagram depicting another example of introducing precursors with sequential emphasis to form doped silicon carbide epitaxial layers and subsidiary structures, according to various embodiments of the invention;

FIG. 7 illustrates a system implementing an epitaxy controller that is configured to form doped SiC epitaxial layers, according to some embodiments of the invention; and

FIG. 8 illustrates an exemplary computer system suitable for forming a doped silicon carbide layer, according to at least one embodiment of the invention.

Like reference numerals refer to corresponding parts throughout the several views of the drawings. Note that most of the reference numerals include one or two left-most digits that generally identify the figure that first introduces that reference number.

### DETAILED DESCRIPTION

Various embodiments or examples of the invention may be implemented in numerous ways, including as a system, a process, an apparatus, or a series of program instructions on a computer readable medium such as a computer readable storage medium or a computer network where the program instructions are sent over optical, electronic, or wireless communication links. In general, operations of disclosed processes may be performed in an arbitrary order, unless otherwise provided in the claims.

A detailed description of one or more examples is provided below along with accompanying figures. The detailed description is provided in connection with such examples, but is not limited to any particular example. The scope is limited only by the claims, and numerous alternatives, modifications, and equivalents are encompassed. Numerous specific details are set forth in the following description in order to provide a thorough understanding. These details are provided as examples and the described techniques may be practiced according to the claims without some or all of the accompanying details. For clarity, technical material that is known in the technical fields related to the examples has not been described in detail to avoid unnecessarily obscuring the description.

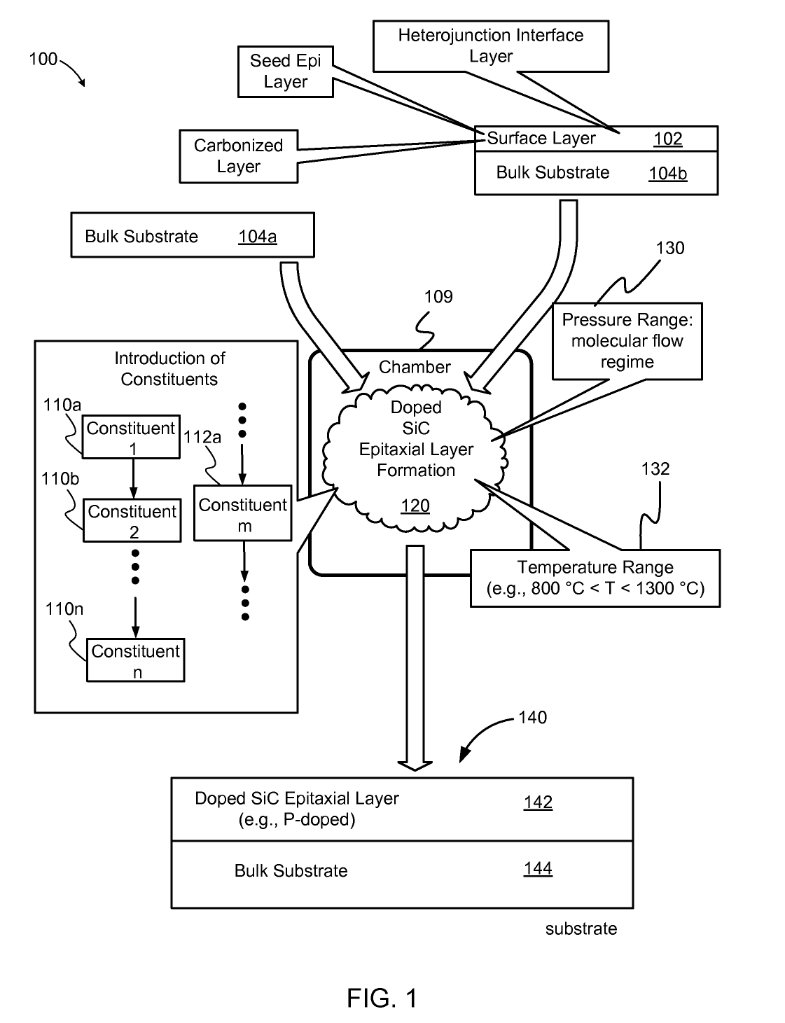

FIG. 1 is a diagram depicting an example of a flow to form doped silicon carbide (e.g., P-doped silicon carbide) on a substrate, according to various embodiments of the invention. In flow 100, processes of doped silicon carbide (“SiC”) epitaxial layer formation 120 can be configured to fabricate a substrate 140 that includes a layer of silicon carbide, such as a doped silicon carbide epitaxial layer 142, and a bulk substrate 144. In some embodiments, doped silicon carbide epitaxial layer 142 can be P-doped. To form doped silicon carbide epitaxial layer 142, a bulk substrate 104a or a bulk substrate 104b is introduced into a chamber 109 to facilitate doped silicon carbide epitaxial layer formation process 120, which can be configured to operate on bulk substrate 104a or a surface layer 102 formed upon bulk substrate 104b. Surface layer 102 can provide a diffusion barrier, at least in some cases, and can include a seed epitaxial layer, a carbonized layer, or any combination thereof. In some embodiments, doped silicon carbide epitaxial layer 142 can include silicon carbide of the form 3C—SiC, as well as any other form or polytype. Doped silicon carbide epitaxial layer formation 120 can introduce two or more constituents 110a to 110n, one or more being introduced with sequential emphasis to form doped silicon carbide epitaxial layer 142. Further, doped silicon carbide epitaxial layer formation 120 can introduce one or more constituents (“m”) 112a in parallel with the introduction of at least one of constituents 110a to 110n. In at least some embodiments, doped silicon carbide epitaxial layer formation 120 can introduce any of constituents 110a to 110n, as well as constituent 112a, into a region (e.g., a volumetric region about and/or adjacent to either bulk substrates 104a or 104b) at a range 130 of pressures that includes a relatively high vacuum to for introducing constituents 110a to 110n, and constituent 112a, in a molecular flow regime at temperatures below, for example, 1,370° C. In at least some embodiments, doped silicon carbide epitaxial layer formation 120 can introduce one or more of constituents 110a to 110n and constituent 112a in a temperature range 132 between, for example, 800° C. and 1300° C. By alternately emphasizing the introduction of one constituent, such as constituent 110a (e.g., a source of silicon), and deemphasizing the other constituent, such as constituent 110b (e.g., a source of carbon), doped silicon carbide epitaxial layer formation 120 can therefore form doped silicon carbide epitaxial layer 142. In at least some embodiments, doped silicon carbide epitaxial layer formation 120 can deemphasize constituent 110b by reducing the availability of constituent 110b to interact with the constituent 110a (or any other constituent or material) to form molecules other than at substrate 140. For example, doped silicon carbide epitaxial layer formation 120 can purge a reactive region or zone to remove (or substantially remove) quantities of constituent 110b. Or, if constituent 112a is introduced during (or substantially during) introduction of constituent 110b, then doped silicon carbide epitaxial layer formation 120 can deemphasize both constituents 110b and 112a prior to introduction of constituent 110n, if applicable, or the re-introduction of constituent 110a. In at least some embodiments, constituent 112a can be sources of dopants, such as p-type dopants, that can be introduced in series and/or in parallel (not shown) with the sources of silicon and carbon, or a combination thereof.

In view of the foregoing, the processes of doped silicon carbide epitaxial layer formation 120 can enhance the structures and/or functionalities of doped silicon carbide epitaxial layer 142. In at least some embodiments, doped silicon carbide epitaxial layer formation 120 can introduce constituents 110a to 110n independent or (substantially independent) from each other to, for example, reduce the collisions between silicon-based molecules of constituent 110a and carbon-based molecules of constituent 110b (as well as collisions with molecules associated with constituent 112a), thereby reducing formation of molecules at locations other than that at the surface of doped silicon carbide epitaxial layer 142. With the reduction of such molecules, doped silicon carbide epitaxial layer 142 can be fabricated with a monocrystalline (or a substantially monocrystalline) structure that can have enhanced crystal quality than otherwise might be the case. Thus, the processes of doped silicon carbide epitaxial layer formation 120 can facilitate formation of atomically flat (or substantially flat) layers or sub-layers of silicon carbide. Further, doped silicon carbide epitaxial layer formation 120 can introduce constituent 112a (e.g., such as a p-type dopant) independent or (substantially independent) from the introduction of at least one of constituents 110a to 110n. Separately introducing constituents 110a to 110n from each other (as well as separately introducing constituent 112a from one or more of constituents 110a to 110n) can also facilitate in a reduction in the formation of molecules that include elements other than silicon and carbon. For example, the quantity of molecules composed of silicon, carbon, and hydrogen (“Si—C—H”) molecules can be reduced (e.g., to negligible or substantially zero amounts). This can reduce stacking faults and twin-related defects. In at least some embodiments, the reduced quantities of molecules other than silicon carbide molecules (e.g., other than 3C SiC), can facilitate enhanced conductivity. Further, the processes of doped silicon carbide epitaxial layer formation 120 can facilitate enhanced growth of doped silicon carbide epitaxial layer 142 to thicknesses of, for example, 20 to 600 nm, or greater, according to at least some embodiments. In at least some embodiments, doped silicon carbide epitaxial layer formation 120 can provide for doped silicon carbide epitaxial layer 142 between temperatures between of 800° C. and 1150° C., thereby enabling doped silicon carbide epitaxial layer formation 120 to accommodate integration with complementary metal oxide semiconductor (“CMOS”) technologies on substrates from, for example, six to eight inches and above. According to some embodiments, doped silicon carbide epitaxial layer formation 120 can provide for enhanced hole mobilities (e.g., using Hall doping concentration), thereby providing for less resistivity as compared, for example, to P-doped SiC processes in which there might be overlapping in the introduction and/or contemporaneous presence of silicon and carbon precursors.

As used herein, the term “sequential emphasis” can refer, at least in some embodiments, to relative amounts of constituents that vary temporally, such as in an alternating or a sequential manner (e.g., a repeated sequential manner), to introduce the sources of silicon and carbon, and sources of dopant. Thus, relative amounts of one or more of the constituents can predominate over one or more other constituents for an interval of time, with subsequent other constituents predominating during other intervals of time. In some embodiments, doped silicon carbide epitaxial layer formation 120 can introduce a predominant constituent in one time interval in amounts that are greater than the other one or more constituents. In at least some embodiments, a predominant constituent can be the only constituent (e.g., approximately 100% of introduced constituent) present during an interval of time, and amounts of the one or more subordinate constituents can be absent (e.g., approximately 0% of introduced constituent) or can be substantially absent. In at least some embodiments, two constituents can be predominant over the others; that is, two constituent can be the only constituents (e.g., approximately 100% of the combined introduced constituents) present during an interval of time, and amounts of the one or more subordinate constituents can be absent (e.g., approximately 0% of introduced constituent) or can be substantially absent. For example, during an interval of time, only the carbon source and the dopant source can be introduced, whereas amounts of the silicon source during that interval can be absent.

In at least some embodiments, at least two of constituents 110a to 110n can be precursors that are introduced in the gaseous phase as sources of silicon and carbon in accordance with various vapor deposition techniques, such as variants of chemical vapor deposition (“CVD”), atomic layer CVD (“ALCVD”), as well as other equivalent techniques. Thus, constituent 112a can be introduced in the gaseous phase as sources of aluminum or other p-type elements. In other embodiments, constituents 110a to 110n and constituent 112a can be used in molecular beam epitaxy, vapor phase epitaxy, liquid phase epitaxy, and other epitaxial techniques that can be modified to accommodate the introduction of constituents 110a to 110n and constituent 112a with sequential emphasis to form doped silicon carbide epitaxial layer 142. Note that while constituent 112a can be described as a p-type dopant, constituent 112a can include n-type dopants, according to other embodiments.

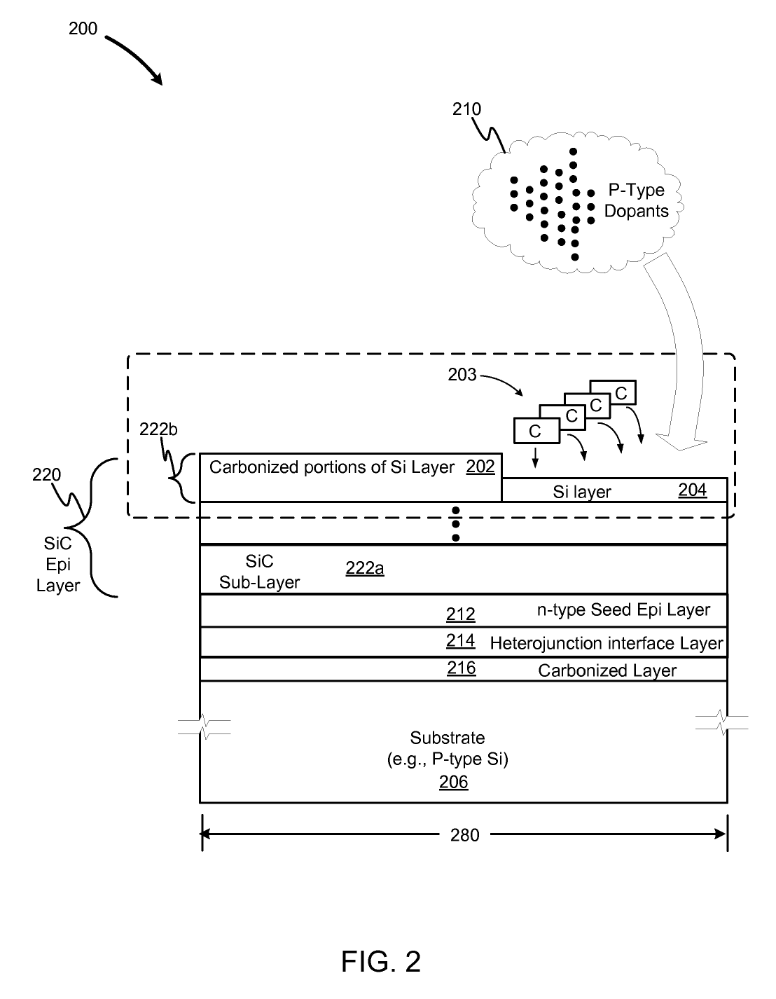

FIG. 2 is a diagram depicting an example of a semiconductor wafer 200 including a P-doped silicon carbide epitaxial layer 220, according to at least some embodiments of the invention. As shown, P-doped silicon carbide epitaxial layer 220 can include multiple doped silicon carbide sub-layers 222a, each of which can be formed in a cycle of alternating silicon and carbon precursors, the cycle including the introduction of a p-type dopant 210. Doped silicon carbide sub-layers 222a can be formed from the reaction of a carbon precursor and a deposited silicon layer, the reaction occurring in the presence of a dopant source for p-type dopant 210. For example, one of doped silicon carbide sub-layers 222a can be formed similar to the formation of a doped silicon carbide sub-layer 222b, whereby sources of carbon (“C”) 203 are introduced to convert (e.g., carbonize) silicon (“Si”) layer 204 in the presence of dopants 210 into doped silicon carbide sub-layer 222b. In some embodiments, p-type dopants 210 can be introduced during portions of cycles that form multiple doped silicon carbide sub-layers 222a. P-type dopants 210 can include acceptor impurities for enhancing the hole carrier concentrations for a structure in substrate 200. In some examples, p-type dopants 210 can include aluminum atoms, or other elements that are suitable to accept electrons.

In some embodiments, doped silicon carbide sub-layers 222a can be formed above or on one or more of the following: an n-type seed epitaxial (“epi”) layer 212 and a heterojunction interface layer 214, any of which can be optional. In some embodiments, semiconductor wafer 200 can include a carbonized layer 216, which can include carbon elements and, optionally, dopants (e.g., n-type dopants). N-type seed epitaxial layer 212 can be an N-doped silicon carbide structure configured to orient the crystalline structure of subsequent P-doped silicon carbide sub-layers 222a. Heterojunction interface layer 214 can be a doped semiconductor structure, such as a p-type semiconductor, that can be configured to reduce current leakage through the silicon/silicon carbide heterojunction. In some embodiments, seed epitaxial (“epi”) layer 212 and heterojunction interface layer 214 can be respectively p-type and n-type, whereas in other embodiments layers 212 and 214 each can include any type of dopant.

Semiconductor wafer 200 can include a bulk material, such as bulk substrate 206, which can include concentrations of dopant impurities. For example, bulk substrate 206 can be doped to be n-type when dopants 210 are, for example, p-type. In other examples, bulk substrate 206 can be doped to be p-type when, for example, dopants 210 are p-type. P-type dopants 210 can provide for doping concentrations of p-type carriers between, for example, 10¹⁵ to 10¹⁹ per cm³. In one example, doping concentrations of p-type carriers can be between, for example, 6×10¹⁶ to 2×10¹⁷ per cm³. In some embodiments, doped silicon carbide sub-layers 222a can have thicknesses of approximately 0.70 nm. In some embodiments, any of doped silicon carbide sub-layers 222a can have a thickness within a range from approximately 0.40 nm (i.e., the low end of the range) to approximately 0.95 nm (i.e., the high end of the range), while in other embodiments, either the low end of the range or the high end of the range, or both, can be less than or greater than the aforementioned values. According to some embodiments, silicon carbide sub-layers 222a can have thicknesses that are equal to or less than silicon layers 204, as the silicon lattice constant can be greater than the silicon carbide lattice constant and the atomic density of SiC can be greater than that of Si. In some embodiments, a seed layer, such as seed 212, can be about 10 nm, or within a range thereabout (e.g., ±30%). In some embodiments, a carbonized layer, such as carbonized layer 216, can be about 2 nm, or within a range thereabout (e.g., ±30%). The processes of doped silicon carbide epitaxial layer formation described herein can facilitate formation of a monocrystalline P-doped silicon carbide epitaxial layer 220 having a thickness up to, or within a range of 20 nm to 600 nm. In some embodiments, P-doped silicon carbide epitaxial layer 220 can be greater than 600 nm. Semiconductor wafer 200 can have a diameter 280 of approximately 150 mm or larger, according to some embodiments. In other embodiments, semiconductor wafer 200 can be composed of any semiconductor material, such as gallium arsenide, etc. In some embodiments, semiconductor wafer 200 can be composed of either p-type or n-type semiconductor material. According to some embodiments, P-doped silicon carbide epitaxial layer 220 can have hole mobilities that can be in, for example, a range from 190 to 250 cm²/V·s.

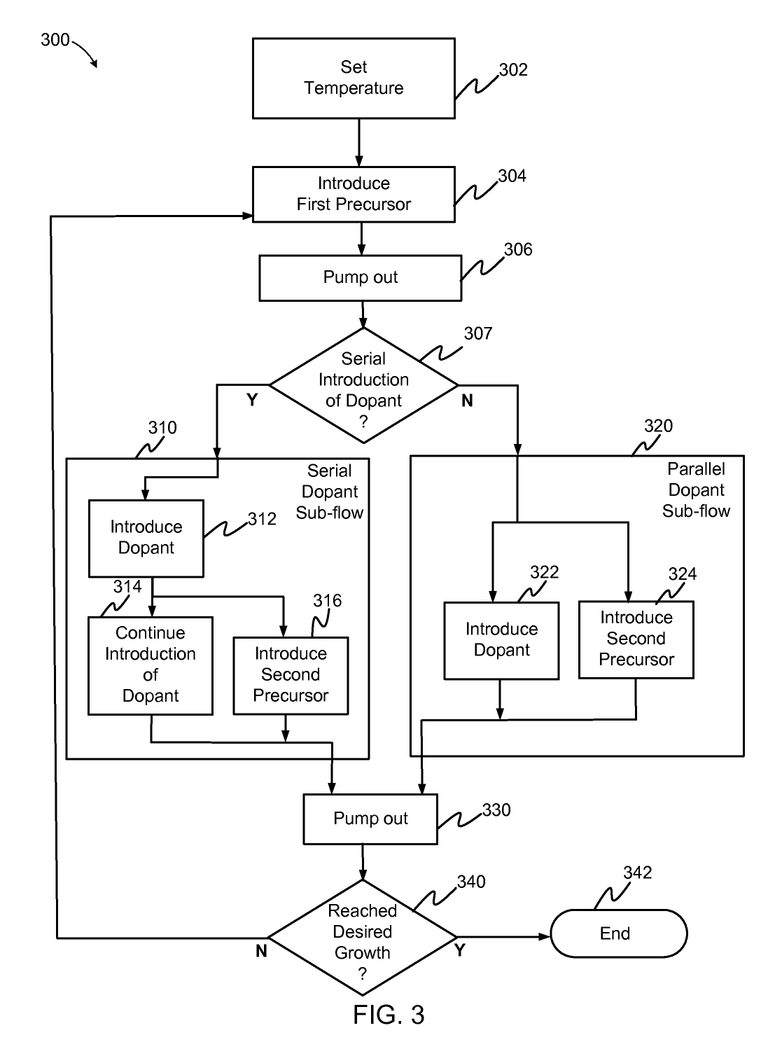

FIG. 3 is a flow diagram depicting an example of a method of forming doped silicon carbide on a bulk substrate, according to various embodiments of the invention. At 302, the surface of the substrate is set to a temperature between, for example, 750° C. and 1300° C. In one embodiment, the temperature can be set within a range of 800° C. and 1150° C., such as at 1000° C. or 1050° C., or any temperate in between. At 304, a precursor, such as a silicon-based gas, can be introduced into a region adjacent to a substrate to deposit a layer (e.g., a silicon layer) on the substrate. Examples of silicon sources include silicon-based gases, such as silane (“SiH₄”) and other gases having the form SiHₓ. Other examples of silicon-based gases include silicon-based gases of the form SiHₓCl_{y}, or the form SiHₓCH_{z}. In yet in other examples, silicon sources can include mixtures of gases, including mixtures of silicon-based gases. One example of such a mixture includes silane (“SiH₄”) and tetrachlorosilane (“SiCl₄”). In some embodiments, a region can be depressurized at 304 to a pressure that can reduce intermolecular collisions between molecules of the precursors (e.g., of the same or different precursors) and/or dopants. Thus, a precursor at 304 can be introduced at pressures sufficient to maintain the molecular flow regime. In the molecular flow regime, the molecular mean free path can be of sufficient length to decrease collisions between gas molecules, as well as between the gas molecules and a chamber wall. In at least some embodiments, the precursor can be introduced at 304 at a pressure (or an approximate pressure) of 9×10⁻⁵ mbar (i.e., 0.00009 mbar), or less. In some other embodiments, the precursor can be introduced at 304 in a range of pressures including pressures of 2.3×10⁻⁵ mbar, such as a range from 1×10⁻⁵ to 9×10⁻⁴ mbar. In some embodiments, these pressures can be applied at subsequent precursor and/or dopant introductions in flow 300, including at sub-flows 310 and 320.

At 306, gaseous materials can be purged from the region. Examples of gaseous materials include excess silicon source material, byproducts of interactions, residual dopants, if any, or any other element and/or molecule in a state that can be evacuated. In some embodiments, purging the region can include pumping out a chamber in which a substrate is disposed. This can decrease the amount of the silicon source in the region (and/or chamber), as well as decreasing the amount of other elements that might contribute to formation of undesirable structures. Thus, at 306, amounts of silicon-based molecules can be decreased to reduce formation of molecules that include, for example, elements other than silicon and the elements of the following precursor (and/or dopant) introduced in the remainder of flow 300 (e.g., such as carbon or any other element).

At 307, a determination is made to pass through either sub-flow 310 or sub-flow 320. In sub-flow 310, a dopant, such as a p-type dopant, can be added as a dopant gas in series with the introduction of a subsequent precursor, such as a carbon-based gas. For example, a dopant can be introduced at 312 prior to the introduction of a second precursor at 316. The introduction of the dopant can continue at 314 in parallel (or substantially in parallel) with the introduction of the second precursor at 316. In some embodiments, 312 can be implemented subsequent to 314 and/or 316 (not shown). In sub-flow 320, the dopant can be added as a dopant gas at 322 in parallel (or substantially in parallel) with the introduction of a second precursor, such as a carbon-based gas, at 324. Note that 307 can be optional, and various embodiments can include either sub-flow 310 or sub-flow 320, or combinations thereof.

At 310, 314 or 322, a dopant can be introduced as a p-type dopant gas into the region adjacent to the substrate. Examples of p-type dopant gases includes aluminum-based dopant gases, including trimethylaluminum (“(CH₃)₃Al”), or TMAl. In other embodiments, the p-type dopant gas can be any other suitable gas that can deliver acceptor impurities to (or adjacent to) the site at which carbon converts silicon into silicon carbide. In one embodiment, the introduction of a p-type dopant gas at 310, 314 or 322 can impede or otherwise reduce the incorporation of other impurities from the environment that might otherwise affect conductivity. For example, the introduction of TMAl may reduce the incorporation of nitrogen (“N”) and/or oxygen (“O”), both of which tend to make the silicon carbide epitaxial layer more n-type.

At 316 or 324, another precursor, such as a carbon-based gas, can be introduced into the region adjacent to the substrate to convert the layer formed at 304 into a doped silicon carbide sub-layer. Examples of carbon sources include carbon-based gases, such as hydrocarbon gases. Examples of carbon-based gases can include acetylene (e.g., C₂H₂) as well as variants thereof having the form C_{X}H_{X}, as well as any hydrocarbon compound having the forms C_{X}H_{2X}, C_{X}H_{2X-2}, C_{X}H_{2X-1} and the like. In some embodiments, the region can be depressurized at any portion of sub-flows 310 or 320 to a pressure similar to a pressure at 304 that can reduce intermolecular collisions between molecules (e.g., of the same or different precursors, or between a precursor and a dopant) at, for example, 312, 314, 316, 322, and 324 to maintain the molecular flow regime. Note that the pressures established at 304 can be maintained thorough flow 300 up through sub-flows 310 or 320, as well as through other portions (e.g., 330) of a cycle of SiC epitaxial layer formation. In some embodiments, the other elements, such as hydrogen, nitrogen, etc., can be added at 316 or 324 as agents to facilitate conversion of silicon layers in the presence of carbon into SiC sub-layers. In at least some embodiments, the precursor can be introduced at 316 or 324 at a pressure (or an approximate pressure) below 10⁻³ mbar, such as at 4.5×10⁻⁴ mbar. In some other embodiments, the precursor can be introduced at 316 or 324 in a range of pressures including pressures of 6.8×10⁻⁵ mbar, such as a range from 1×10⁻⁵ to 9×10⁻⁴ mbar. In some embodiments, the second precursor can be introduced at 316 or 324 at a pressure (or an approximate pressure) of 9×10⁻⁵ mbar (i.e., 0.00009 mbar), or less.

At 330, gaseous materials can be purged from the region. Examples of gaseous materials include excess carbon source material, byproducts of interactions, residual dopant, or any other element and/or molecule in a state that can be evacuated. In some embodiments, purging the region can include pumping out a chamber in which a substrate is disposed. This can decrease the amount of the carbon source and/or dopant source in the region (and/or chamber). Thus, at 330, amounts of carbon-based molecules and/or aluminum-based molecules can be decreased to reduce formation of molecules that include, for example, elements other than silicon and carbon that might contribute to the formation of fabrication-related defects, such as stacking faults and twin-related defects. For example, pumping out the region adjacent to the substrate can reduce the quantity of molecules composed of silicon, carbon, and another element, such as hydrogen or a dopant element, to negligible or substantially zero amounts. Thus, purging the region at 330 (and/or at 306) can reduce the quantities of Si—C—H molecules, as well as other molecules that might include elements other than silicon and carbon.

At 340, a determination is made as to whether the silicon carbide epitaxial layer has reached its desired growth (or thickness). If not, flow 300 continues to 304, and, if so, flow 300 terminates at 342. In various embodiments, a cycle from 304 to 330 can be repeated any number of times to form any thickness of silicon carbide epitaxial layer. In some examples, flow 300 can be performed for about 600 cycles to form silicon carbide epitaxial layers with thicknesses from approximately 240 nm (e.g., 0.40 nm/cycle) to approximately 570 nm (e.g., 0.95 nm/cycle). In one example, flow 300 can form a silicon carbide epitaxial layer at the rate of 0.60 nm/cycle.

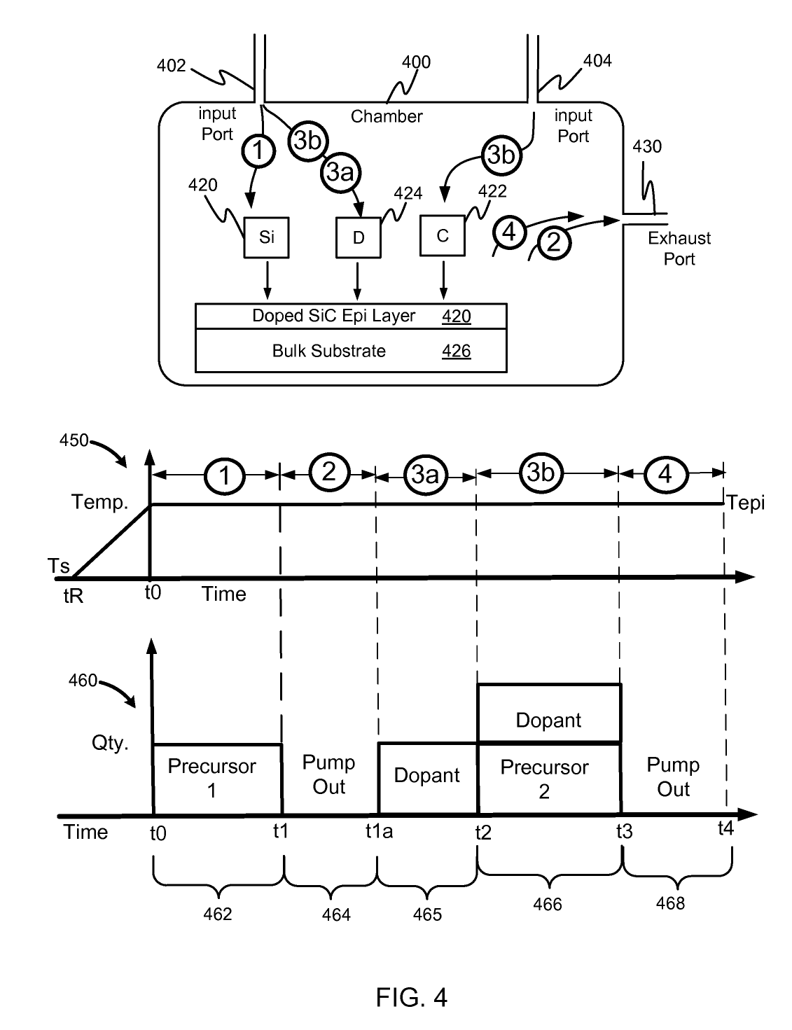

FIG. 4 is a diagram depicting an example of introducing precursors with sequential emphasis to form a doped silicon carbide epitaxial layer, according to various embodiments of the invention. FIG. 4 depicts examples of temperature characteristics 450 over time and quantities (“Qty.”) 460 of precursors and dopants over time for fabricating a doped silicon carbide epitaxial (“SiC Epi”) layer 420 upon a bulk substrate 426 in chamber 400. As shown in temperature characteristics 450, the temperature can be ramped from start temperature, Ts, to one or more epitaxial temperatures, Tepi, which is the temperature at which the epitaxial growth can occur. In some embodiments, start temperature, Ts, can describe the temperature prior to epitaxial growth, and the start temperature can be within the range from about 600° C. to 800° C. In other embodiments, the start temperature, Ts, can be any temperature, including an ambient temperature. In some embodiments, epitaxial temperature, Tepi, can be within the range from about 800° C. and 1300° C. For example, the epitaxial temperature can be approximately 1000° C. or 1050° C., or any temperature in between. Therefore, the surface of bulk substrate 426 and/or the interior of chamber 400 can be ramped from start temperature, Ts, to epitaxial temperature, Tepi, at a rate of about 5° C./minute from ramp time, tR, to time zero, t0, according to some embodiments.

To illustrate the introduction of precursors as well as dopant, consider that during interval 462 precursor one is introduced with emphasis via input port 402 into chamber 400 as a source of, for example, silicon (“Si”) elements 420. Interval 462 can be described as phase one, as denoted by encircled numeral 1, that can extend from time zero, t0, to time one, t1. In some embodiments, a silicon source can be introduced at flow rates, for example, from approximately 0.05 standard cubic centimeters per minute (“sccm”) to approximately 2.0 sccm. An example of a flow rate for interval 462 can be 1.5 sccm. In one embodiment, the flow rate at which the silicon source is introduced can be between 0.05 sccm and 0.1 sccm. In some embodiments, interval 462 can range from approximately ten seconds to approximately sixty seconds. For example, interval 462 can last for approximately 24 seconds.

During interval 464, a pump out operation can be performed to evacuate via exhaust port 430 materials prior to the introduction of the next precursor. Interval 464 can be described as phase two, as denoted by encircled numeral 2, that can extend from time one, t1, to time one a, t1a. Interval 464 can range from five seconds to sixty seconds, according to some embodiments. For example, interval 464 can be 40 seconds.

During interval 465, a dopant can be introduced via input port 402 (or any other port) into chamber 400 as a source of, for example, p-type dopant (“D”) 424 elements (e.g., TMAl or other sources of aluminum). Interval 465 can be described as “phase three a,” as denoted by encircled numeral 3a, that can extend from time one a, t1a, to time two, t2. In some embodiments, the source of aluminum can be introduced at flow rates, for example, from approximately 0.04 sccm to approximately 15 sccm. Examples of flow rates for interval 465 include 0.05 sccm and 0.1 sccm. In some embodiments, interval 465 can range from approximately ten seconds to approximately sixty seconds. For example, interval 465 can be 20 seconds. Note that in other embodiments, interval 465 can be omitted, or can be disposed after “phase three b” (i.e., after interval 466).

During interval 466, precursor two is emphasized and can be introduced via input port 404 (or any other port) into chamber 400 as a source of, for example, carbon (“C”) 422 elements. Interval 466 can be described as “phase three b,” as denoted by encircled numeral 3b, that can extend from time two, t2, to time three, t3. Further, the dopant can be introduced (or can be continually introduced from interval 465) via input port 402 (or any other port) into chamber 400 as a source of p-type dopant (“D”) 424 elements. In some embodiments, a carbon source can be introduced at flow rates, for example, from approximately 0.05 sccm to approximately 15 sccm. Examples of flow rates for the carbon source for interval 466 include 0.3, 1.5, 8, and 10 sccm. The flow rates for the dopant source for interval 466 can be equivalent or similar to flow rates used in interval 465. In some embodiments, interval 466 can range from approximately five seconds to approximately sixty seconds. For example, interval 466 can be approximately 10 seconds. During interval 466, the silicon layer formed in interval 462 can be converted into a doped silicon carbide sub-layer by carbonizing the silicon layer (e.g., by enabling carbon to interact with silicon in the silicon layer) in the presence of dopants and carbon sources.

During interval 468, a pump out operation can be performed to evacuate materials via exhaust port 430 prior to the introduction of the next precursor, such as the precursor introduced during interval 462. Interval 468 can be described as phase four, as denoted by encircled numeral 4, that can extend from time three, t3, to time four, t4. Interval 468 can range from five seconds to sixty seconds, according to some embodiments. For example, interval 468 can be 40 seconds. In some embodiments, input port 402 and input port 404 can be the same port. In some embodiments, interval 462 can begin at time tR. In some embodiments, dopants can be added during interval 462. Note that the concentrations of the dopants in intervals 465 and 466, as well as interval 462, if applicable, can be adjusted by modifying either the flow rates or the supply times (e.g., length of intervals 462, 465 or 466), or both the flow rates and supply times. For example, the flow rates and supply times during intervals 465 and 466 (and, in some cases, interval 462) can be configured to provide concentrations of p-type carriers from 10¹⁵ to 10¹⁹ per cm in the silicon carbide epitaxial layer. Note that the relative amounts of quantities 460 of precursors PC1 and PC2 and dopants need not be to scale.

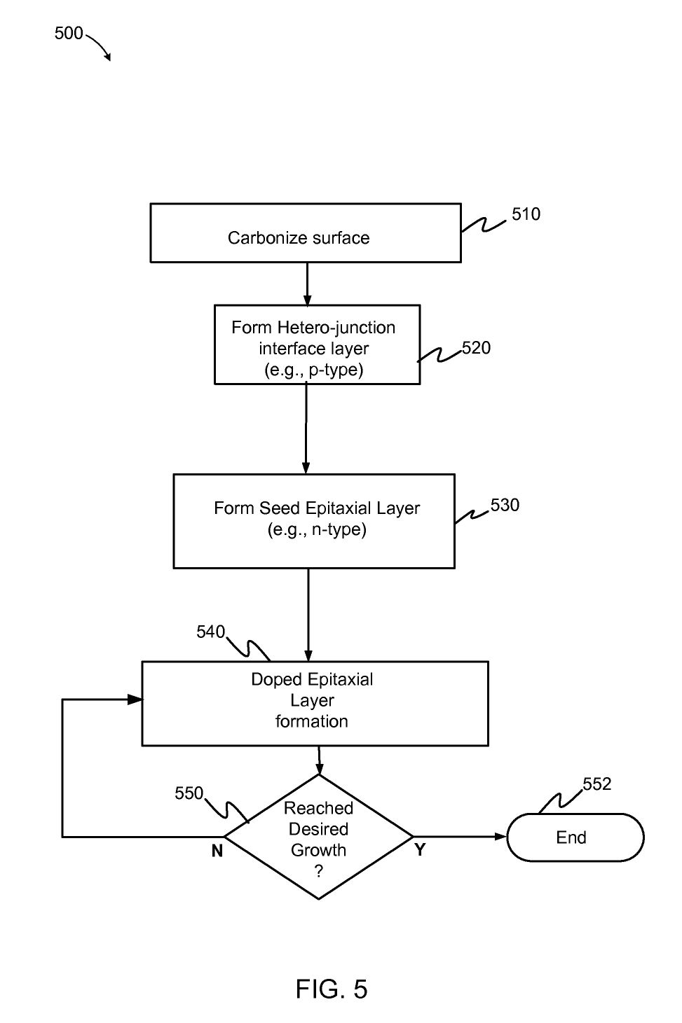

FIG. 5 is a flow diagram depicting another example of a method of forming doped silicon carbide on a bulk substrate, according to various embodiments of the invention. At 510, a carbonized surface can be formed on a bulk substrate. The carbonized surface layer can passivate the bulk substrate to reduce carbon diffusion into the bulk substrate and/or reduce silicon outdiffussion, thereby reducing etch pits and SiC over-etch pits, respectively, prior to (or during) silicon carbide epitaxial layer formation. In at least some embodiments, the carbonized surface layer can be one to two monolayers thick, inclusively. In other embodiments, the carbonized surface layer can be less than 1 to 2 nm thick.

At 520, a heterojunction interface layer can be formed by, for example, forming the seed epitaxial layer. In some embodiments, the heterojunction interface layer is a p-type semiconductor structure can be formed above or on the carbonized surface layer. In at least some embodiments, the heterojunction interface layer can have a thickness in the range of 1 to 20 nm thick. In at least some embodiments, the heterojunction interface layer can include doping concentrations of p-type carriers between, for example, 10¹⁵ to 10¹⁹ per cm³.

At 530, a seed epitaxial layer can be formed by, for example, forming the seed epitaxial layer. In some embodiments, the seed epitaxial layer can be formed above or on the heterojunction interface layer. In at least some embodiments, the seed epitaxial layer can be in the ranges of 5 to 20 nm thick. For example, the seed epitaxial layer can be formed to be about 10 nm. In some embodiments, the seed epitaxial layer can include doping concentrations of n-type carriers between, for example, 10¹⁵ to 10¹⁹ per cm³. While the n-type dopants can be introduced as constituents in some embodiments, or the n-type dopants can be supplied from the environment (e.g., such as oxygen).

At 540, a doped silicon carbide epitaxial layer can be formed on the seed epitaxial layer as a sub-flow that can be similar to flow 300 of FIG. 3. At 550, a determination is made as to whether the silicon carbide epitaxial layer has reached its desired growth (or thickness). If not, flow 500 continues to 540, and, if so, flow 500 terminates at 552. In at least one embodiment, flow 500 can be implemented in-situ; that is, without removing a wafer or substrate from a chamber. Rather, flow 500 facilitates performance of 510, 520, 530 and 540 in a single chamber, for example. In some instances, this can facilitate a reduction in transporting wafers and substrates in relation to different fabrication equipment. In at least one embodiment, flow 500 can continue from 540 to 510 to add a carbonized surface layer after each cycle of 540, with flow 500 skipping 520 and 530 to continue to the next cycle at 540.

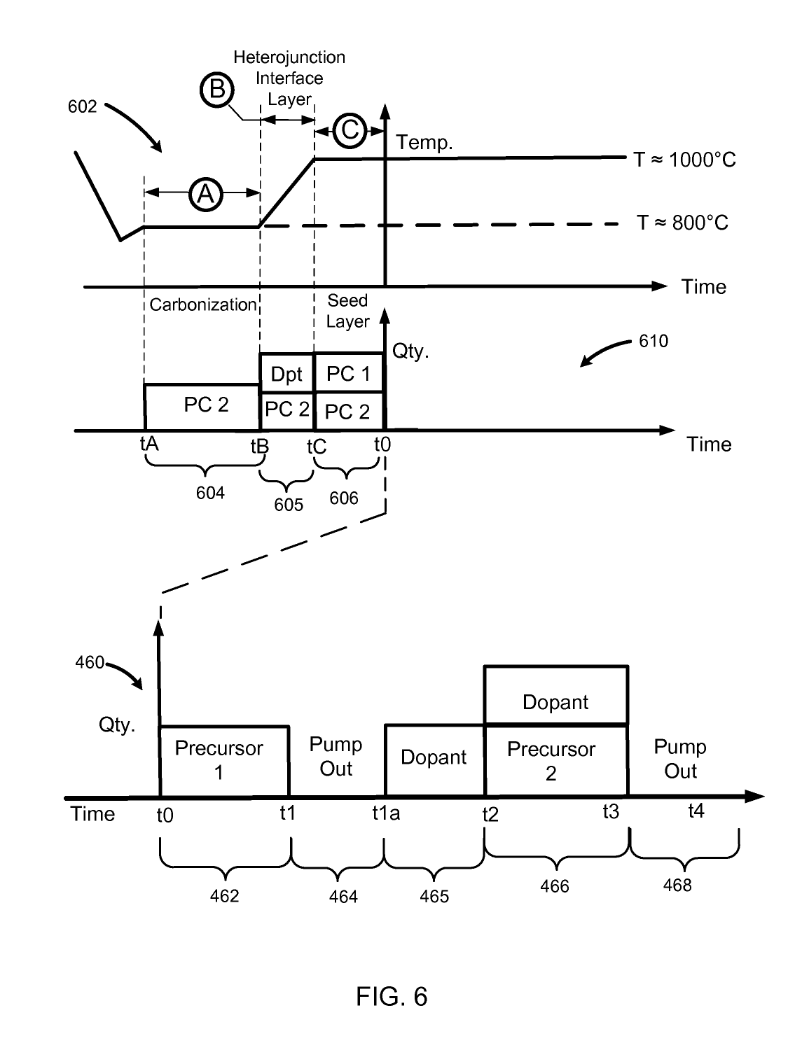

FIG. 6 is a diagram depicting another example of introducing precursors with sequential emphasis to form doped silicon carbide epitaxial layers and subsidiary structures, according to various embodiments of the invention. FIG. 6 depicts examples of temperature characteristics 602 over time, and quantities (“Qty.”) 610 of precursors and dopants over time to facilitate carbonization (i.e., forming a carbonized surface layer, or “carbonized layer”) and seed layer growth, as well as optional formation of a heterojunction interface layer. As shown, the temperature can be ramped, for example, down from a temperature used to activate (e.g., clean) the surface of a bulk substrate. For example, the temperature can be ramped down prior to time tA from approximately 1000° C. to approximately 750° C. To form the carbonized surface layer, the temperature can be ramped from approximately 750° C. to approximately 800° C., at a rate of, for example, 5° C./minute. Then, a precursor, such as precursor two (“PC2”) (e.g., source of carbon) can be introduced during interval 604 at flow rates of approximately 10 sccm, and at pressures of approximately 0.02 mbar. In some embodiments, flow rates and pressures can be within ranges (e.g., ±20%) about 10 sccm and 0.02 mbar, respectively. In some embodiments, pressures can be above 0.02 mbar. Interval 604 can be described as phase A, as denoted by encircled letter A, that can extend from time tA to time tB. An example of precursor two, PC2, is acetylene (e.g., C₂H₂).

After the carbonized surface layer is formed, then the temperature can be ramped up, for example, from approximately 800° C. to approximately 1000° C. at a rate of, for example, 5° C./minute during interval 605 to form a heterojunction interface layer. Interval 605 can be described as phase B, as denoted by encircled letter B, that can extend from time tB to time tC. In some embodiments, a dopant source (“Dpt”) can be introduced at a flow rate of 0.1 sccm (or at other flow rates for dopants described herein), and a carbon source (shown as “PC2”) can be introduced at a flow rate of 1.5 sccm (or at other flow rates for carbon described herein). In interval 605, examples of sources of dopant (“Dpt”) include TMAl, etc., and examples of sources of carbon (“PC2”) include C₂H₂, C₃H₆, etc. In some embodiments, interval 605 can be described as the time period during which the temperature ramps up from approximately 800° C. to approximately 1000° C., and/or the period time during which either the dopant source or carbon source, or both, are introduced. Thus, while the temperature can ramp up from approximately 800° C. to approximately 1000° C. in, for example, 40 minutes (e.g., interval 605), the introduction of the dopant source or carbon source can be for one or more time periods that individually or collectively are less than 40 minutes (e.g., a portion of interval 605). In at least one embodiment, hydrogen (“H2”) gas, nitrogen (“N2”) gas, or other suitable gases can accompany the introduction of the dopant source and carbon source in interval 605.

During interval 606 at least two precursors can be supplied concurrently to form a seed epitaxial layer, according to some embodiments. Interval 606 can be described as phase C, as denoted by encircled letter C, that can extend from time tC to time t0. In some embodiments, a silicon source (“PC1”), such as SiH₄, can be introduced at a flow rate of 1.5 sccm, and a carbon source (“PC2”), such as C₂H₂, can be introduced at a flow rate of 1.5 sccm. In some embodiments, interval 606 can be approximately thirty minutes. In some embodiments, interval 606 can begin at time tB. After the seed epitaxial layer is formed, then the quantities (“Qty.”) 460 of precursors and dopants over time can be supplied in an alternating manner, whereby the precursors can be introduced during separate intervals 462 and 466. Intervals 464 and 468 can be interleaved with the intervals 462 and 466 to pump out gaseous materials. Intervals 462, 464, 466, and 468 can be equivalent or similar to those of FIG. 4, according to some embodiments.

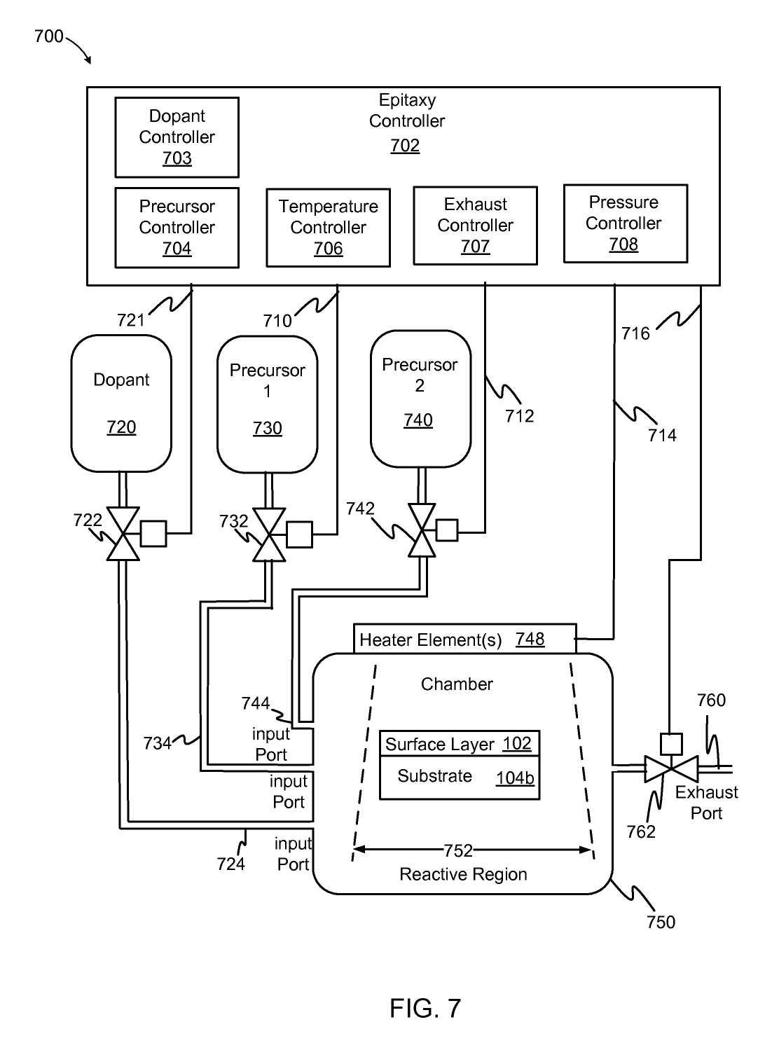

FIG. 7 illustrates a system implementing an epitaxy controller that is configured to form doped SiC epitaxial layers, according to some embodiments of the invention. System 700 can include an epitaxy controller 702, a reservoir 720 (e.g., a gas tank) of dopant (e.g., p-type dopants, such as TMAl), a reservoir 730 (e.g., a gas tank) of precursor 1, such as silicon gas, a reservoir 740 (e.g., a gas tank) of precursor 2, such as carbon gas, a heater element or elements 748, and a chamber 750, which can be configured as a tube-like structure. Note that heater element 748 is depicted as a representative mechanism by which to heat substrate 104b and/or region 752 by way of, for example, infrared heating, RF heating, etc. Thus, heater element 748 need not be configured to heat the walls of chamber 750, and, as such, the walls of chamber 750 can facilitate “cold wall” epitaxy, according to some embodiments. In some embodiments, however, heater element 748 can provide for “hot wall” epitaxy. As shown, a substrate 104b (with or without a surface layer 102) can be disposed in a reactive region 752 at which sources of silicon, carbon, and a dopant can be introduced.

Epitaxy controller 702 can include a dopant controller 703, a precursor controller 704, a temperature controller 706, an exhaust controller 707, and a pressure controller 708. Precursor controller 704 can be configured to control the introduction of the precursors into chamber 750. For example, during one interval of time, precursor controller 704 can transmit control signals via path 710 to control valve 732, which can open to provide a precursor from reservoir 730 via input port 734 to reaction region 752. Similarly, precursor controller 704 also can transmit control signals via path 712 to control valve 742, which can open to provide a precursor from reservoir 740 via input port 744 to reaction region 752. Dopant controller 703 can be configured to control the introduction of dopants into chamber 750. Dopant controller 703 can transmit control signals via path 721 to control valve 722, which can open to provide a dopant from reservoir 720 via input port 724 to reaction region 752. For example, during one interval of time (e.g., interval 465 of FIG. 6), dopant controller 703 can be configured to introduce a dopant when valves 732 and 744 are closed (i.e., no precursors are introduced into chamber 750). During another interval of time (e.g., interval 466 of FIG. 6), dopant controller 703 and precursor controller 704 can be configured to concurrently introduce a dopant and precursor 2, respectively, into chamber 750. Temperature controller 706 can be configured to transmit control signals via path 714 to one or more heater elements 748 to ramp up and down the temperatures, as well as to maintain the temperature at an epitaxial temperature. Exhaust controller 707 can be configured to transmit control signals via path 716 to control valve 762 to facilitate pumping out gaseous material out through an exhaust port 760. In some embodiments, pressure controller 708 can be configured to maintain reactive region 752 at a relatively high vacuum to introduce the precursors in the molecular flow regime. In some embodiments, a relatively high vacuum can be described by pressures (or approximate pressures) of 1×10⁻³ mbar or less, including pressures of 9×10⁻⁵ mbar (i.e., 0.00009 mbar) or less.

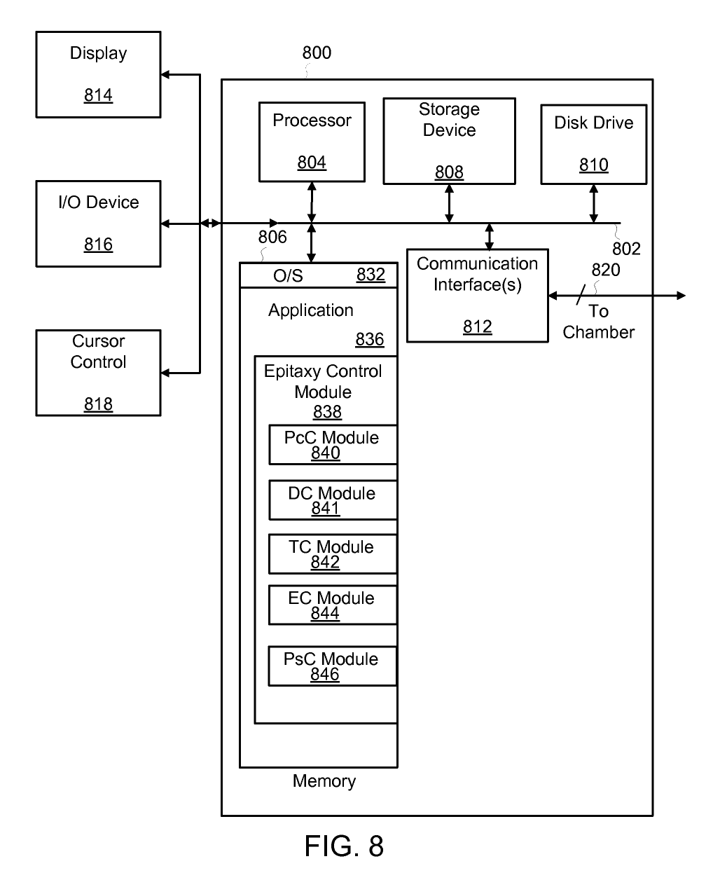

FIG. 8 illustrates an exemplary computer system suitable for forming a doped silicon carbide layer, according to at least one embodiment of the invention. In some examples, computer system 800 can be used to implement computer programs, applications, methods, processes, or other software to perform the above-described techniques and to realize the structures described herein. Computer system 800 includes a bus 802 or other communication mechanism for communicating information, which interconnects subsystems and devices, such as one or more processors 804, system memory (“memory”) 806, storage device 808 (e.g., ROM), disk drive 810 (e.g., magnetic or optical), communication interface 812 (e.g., a modem, Ethernet card, or any other interface configured to exchange data with a communications network or to control a fabrication machine), display 814 (e.g., CRT or LCD), input device 816 (e.g., keyboard), and pointer cursor control 818 (e.g., mouse or trackball). In one embodiment, pointer cursor control 818 invokes one or more specialized commands that can configure one or more of the following: the flow rates and the timing for the introduction of precursors and dopants, the temperature characteristics (e.g., ramping up, ramping down, and maintaining at relatively quiescent temperature) during various phases of the formation of a SiC epitaxial layer, the pressures for the phases of the SiC epitaxial layer formation, and/or the rate and the timing of pumping out a chamber, as well as other parameters that can influence silicon carbide formation.

According to some examples, computer system 800 performs specific operations in which processor 804 executes one or more sequences of one or more instructions stored in system memory 806. Such instructions can be read into system memory 806 from another computer readable medium, such as static storage device 808 or disk drive 810. In some examples, hard-wired circuitry can be used in place of or in combination with software instructions for implementation. In the example shown, system memory 806 includes modules of executable instructions for implementing an operation system (“O/S”) 832, an application 836, and an epitaxy control module 838, which, in turn, can implement a precursor controller (“PcC”) module 840, a dopant controller (“DC”) module 841, a temperature controller (“TC”) module 842, a exhaust controller (“EC”) module 844, and a pressure controller (“PsC”) module 846, each of which can provide functionalities described herein.

The term “computer readable medium” refers, at least in one embodiment, to any medium that participates in providing instructions to processor 804 for execution. Such a medium can take many forms, including but not limited to, non-volatile media, volatile media, and transmission media. Non-volatile media includes, for example, optical or magnetic disks, such as disk drive 810. Volatile media includes dynamic memory, such as system memory 806. Transmission media includes coaxial cables, copper wire, and fiber optics, including wires that comprise bus 802. Transmission media can also take the form of electromagnetic, acoustic or light waves, such as those generated during radio wave and infrared data communications.

Common forms of computer readable media includes, for example, floppy disk, flexible disk, hard disk, magnetic tape, any other magnetic medium, CD-ROM, any other optical medium, punch cards, paper tape, any other physical medium with patterns of holes, RAM, PROM, EPROM, FLASH-EPROM, any other memory chip or cartridge, time-dependent waveforms, or any other medium from which a computer can read instructions.

In some examples, execution of the sequences of instructions can be performed by a single computer system 800. According to some examples, two or more computer systems 800 coupled by communication link 820 (e.g., links to LAN, PSTN, or wireless network) can perform the sequence of instructions in coordination with one another. Computer system 800 can transmit and receive messages, data, and instructions, including program code (i.e., application code) through communication link 820 and communication interface 812. Received program code can be executed by processor 804 as it is received, and/or stored in disk drive 810, or other non-volatile storage for later execution. In one embodiment, system 800 (or a portion thereof) can be integrated into a furnace for performing various deposition techniques, such as variants of chemical vapor deposition (“CVD”), etc.

In at least some examples, the structures and/or functions of any of the above-described features can be implemented in software, hardware, firmware, circuitry, or a combination thereof. Note that the structures and constituent elements above, as well as their functionality, may be aggregated with one or more other structures or elements. Alternatively, the elements and their functionality may be subdivided into constituent sub-elements, if any. As software, the above-described techniques may be implemented using various types of programming or formatting languages, frameworks, syntax, applications, protocols, objects, or techniques. As hardware and/or firmware, the above-described techniques may be implemented using various types of programming or integrated circuit design languages, including hardware description languages, such as any register transfer language (“RTL”) configured to design field-programmable gate arrays (“FPGAs”), application-specific integrated circuits (“ASICs”), or any other type of integrated circuit. These can be varied and are not limited to the examples or descriptions provided.

The description, for purposes of explanation, uses specific nomenclature to provide a thorough understanding of the invention. However, it will be apparent that specific details are not required in order to practice the invention. In fact, this description should not be read to limit any feature or aspect of to any embodiment; rather features and aspects of one example can readily be interchanged with other examples. Notably, not every benefit described herein need be realized by each example of the invention; rather any specific example may provide one or more of the advantages discussed above. In the claims, elements and/or operations do not imply any particular order of operation, unless explicitly stated in the claims. It is intended that the following claims and their equivalents define the scope of the invention.

1. A method of forming an epitaxial layer of silicon carbide, the method comprising:
depositing a layer on a substrate in the presence of a silicon source;
purging gaseous materials subsequent to depositing the layer;
introducing a source of p-type dopant;
converting the layer into a silicon carbide sub-layer in the presence of a carbon source to include the p-type dopant; and
purging other gaseous materials subsequent to converting the layer,
wherein the presence of the silicon source is independent from the presence of the carbon source.

2. The method of claim 1 wherein converting the layer into the silicon carbide sub-layer comprises:
introducing the carbon source substantially coincident to the introduction of the source of the p-type dopant.

3. The method of claim 1 further comprising:
introducing the carbon source; and
introducing a portion of the source of the p-type dopant separate from introducing the carbon source.

4. The method of claim 3 wherein the portion of the source of the p-type dopant is introduced between purging the gaseous materials and purging the other gaseous materials.

5. The method of claim 1 further comprising:
introducing the substrate into a reactive region prior to depositing the layer,
wherein the substrate has a carbonized film formed thereon.

6. The method of claim 5 wherein the carbonized film is configured to impede diffusion of elements with respect to the substrate.

7. The method of claim 5 further comprising:
ramping a temperature of the carbonized film to a target temperature; and
forming a seed epitaxial layer.

8. The method of claim 1 further comprising:
ramping a temperature of the carbonized film to a target temperature; and
introducing the carbon source and the p-type dopant during ramping the temperature to form a p-type heterogeneous interface layer.

9. The method of claim 1 wherein purging the gaseous materials and purging the other gaseous materials comprise:
pumping out a region at which the substrate is disposed.

10. The method of claim 9 wherein pumping out the region at which the substrate reduces formation of molecules that include silicon and carbon other than at the substrate.

11. The method of claim 1 wherein purging the gaseous materials and purging the other gaseous materials respectively comprise:
pumping out a chamber in which the substrate is disposed to decrease the amount of the silicon source in the chamber; and
pumping out the chamber to decrease the amount of the carbon source in the chamber.

12. The method of claim 1 wherein the source of the p-type dopant comprises:
trimethylaluminum (“(CH₃)₃Al”).

13. The method of claim 1 wherein depositing the layer in the presence of the silicon source comprises:
depositing the layer in the presence of a silicon-based gas.

14. The method of claim 13 wherein the silicon-based gas comprises:
silane (“SiH₄”).

15. The method of claim 1 wherein converting the layer into the silicon carbide sub-layer comprises:
converting the layer into the silicon carbide sub-layer in the presence of a carbon-based gas.

16. The method of claim 15 wherein the carbon-based gas comprises:
acetylene (“C₂H₂”).

17. The method of claim 1 further comprising:
depositing another layer on the silicon carbide sub-layer in the presence of the silicon source;
purging the gaseous materials subsequent to depositing the another layer;
introducing the source of the p-type dopant;
converting the another layer into another silicon carbide sub-layer in the presence of the carbon source to include the p-type dopant; and
purging the other gaseous materials subsequent to converting the another layer.

18. A method of forming an epitaxial layer of silicon carbide, the method comprising:
depressurizing the chamber to a pressure that reduces intermolecular collisions between molecules of the precursors;
alternating introduction of precursors adjacent to a surface of a substrate in a chamber;
introducing a p-type dopant substantially during the introduction of one of the precursors; and
purging the chamber subsequent to introduction of each of the precursors.

19. The method of claim 18 wherein alternating the introduction of the precursors comprises:
introducing a silicon gas into the chamber during a first time interval; and
introducing a hydrocarbon gas and the p-type dopant into the chamber during a second time interval,
wherein the hydrocarbon gas is substantially absent during the first time interval and the silicon gas is substantially absent during the second time interval.

20. The method of claim 18 wherein depressurizing the chamber to the pressure comprises:
increasing a first mean free path distance in which a silicon gas molecule collides with another during the first time interval; and
increasing a second mean free path distance in which a hydrocarbon gas molecule collides with another during the second time interval.

21. The method of claim 18 wherein alternating the introduction of the precursors comprises:
alternating deposition of a silicon layer and conversion of the silicon layer to form a sub-layer of silicon carbide.

22. The method of claim 21 further comprising:
forming the epitaxial layer by repeatedly alternating deposition of the silicon layer and converting the silicon layer into the sub-layer of silicon carbide.

23. The method of claim 18 further comprising:
forming the epitaxial layer to include an acceptor element that accepts mobile electrons.

24. The method of claim 23 further comprising:
adding aluminum as the acceptor element.

25. The method of claim 18 wherein alternating the introduction of the precursors comprises:
alternating the introduction of a silicon gas and a hydrocarbon gas at temperatures between 850° C. and 1300° C., inclusively.

26. The method of claim 18 wherein alternating the introduction of the precursors comprises:
alternating the introduction of a silicon gas and a hydrocarbon gas at pressures less than 0.0010 mbar.

27. The method of claim 18 further comprising:
forming an n-type seed epitaxial layer.

28. The method of claim 27 wherein forming the n-type seed epitaxial layer comprises:
introducing a silicon gas substantially simultaneous to introduction of a hydrocarbon gas.

29. A semiconductor wafer comprising:
a substrate including a bulk material;
an heterojunction interface layer; and
a stack of silicon carbide sub-layers constituting a monocrystalline epitaxial layer, each of the silicon carbide sub-layers comprising:
carbonized layers of silicon.

30. The semiconductor wafer of claim 29 wherein heterojunction interface layer comprises:
a material including carbon and a p-type dopant.

31. The semiconductor wafer of claim 29 wherein the stack of silicon carbide sub-layers comprises:
a p-type dopant.

32. The semiconductor wafer of claim 31 wherein the p-type dopant includes a doping concentration between 10¹⁵ and 10¹⁹ per cm³.

33. The semiconductor wafer of claim 29 further comprising:
an n-type seed epitaxial layer disposed between the heterojunction interface and the stack of silicon carbide sub-layers.

34. The semiconductor wafer of claim 29 wherein each of the silicon carbide sub-layers is less than approximately 0.95 nm thick.

35. The semiconductor wafer of claim 29 wherein the monocrystalline epitaxial layer has a thickness that is within a range of 20 nm to 600 nm.

36. The semiconductor wafer of claim 29 wherein the semiconductor wafer has a diameter of approximately 150 mm or larger.
